(19) United States
(12) Patent Application Publication
(10) Pub. No.: US 2024/0103187 A1
(43) Pub. Date: Mar. 28, 2024

(54) RADIATION DETECTOR AND METHOD OF FORMING A RADIATION DETECTOR

(71) Applicant: Thermo Fisher Scientific Messtechnik GmbH, Erlangen (DE)

(72) Inventor: Erich LEDER, Heroldsbach (DE)

(73) Assignee: Thermo Fisher Scientific Messtechnik GmbH, Erlangen (DE)

(21) Appl. No.: 18/474,924

(22) Filed: Sep. 26, 2023

Related U.S. Application Data
(60) Provisional application No. 63/377,207, filed on Sep. 27, 2022.

(51) Int. Cl. G01T 1/20; H01L 27/146

(52) U.S. Cl. CPC G01T 1/2018; H01L 27/14618; H01L 27/14663; H01L 27/14683

(57) ABSTRACT

A radiation detector is described. The detector includes a silicon photomultiplier, a scintillator, and a layer comprising metal that is spaced from the scintillator. The scintillator is arranged to emit light towards the silicon photomultiplier. The layer comprising metal is configured to receive incident light radiation and to provide additional radiation to the scintillator in response to the received incident radiation. A method of forming such a radiation detector is also described.

### FIELD OF THE INVENTION

This disclosure relates to a radiation detector and to a method of forming a radiation detector.

### BACKGROUND OF THE INVENTION

Radiation detectors, such as those implemented in dosimeters, are known for determining radiation levels in hazardous environments, which is useful in helping to protecting users from exposure to such radiation.

Personal Radiation Detectors (PRDs) capable of measuring gamma radiation are known and used to alert users to exposure to dangerous levels of radiation by measuring dose rates with high precision in a wide photon energy range ˜50 keV to 3 MeV. However, PRD embodiments may have limitations for measurements of what is generally referred to as “high dose rate” radiation.

Some PRDs utilize pin diode detectors and Geiger-Muller detectors. PRDs generally exploit atomic or molecular excitation produced by radiation passing through a scintillation material. Subsequent de-excitation generates photons of light that can be measured to give an indication of the energy deposited in the detector by the radiation. For example, a detector may include scintillation material coupled to a photomultiplier. When the detector is exposed to radiation, the scintillation material is excited, generating photons of visible light. This light then strikes the photomultiplier, which amplifies the result and generates a signal that can be measured.

US-2021/278550 describes a radiation detector that includes a printed circuit board and a detector assembly operably connected to the printed circuit board. The detector assembly includes a silicon photomultiplier (SiPM) and an organic scintillator coating applied to a surface of the SiPM. A reflective foil covers the organic scintillator coating. A light sealing cover is secured to the printed circuit board such that the SiPM and the organic scintillator are encapsulated within the light sealing cover. An optical reflector is positioned on the scintillator and may create additional electrons, thereby improving the performance of detector.

WO-2015/081134 describes techniques for systems and methods using SiPM based radiation detectors to detect radiation in an environment. An SiPM-based radiation detection system may include a number of detector assemblies, each including at least one scintillator providing light to a corresponding SiPM in response to ionizing radiation entering the scintillator. The radiation detection system may include a logic device and a number of other electronic modules to facilitate reporting, calibration, and other processes. The logic device may be adapted to process detection signals from the SiPMs to implement different types of radiation detection procedures. The logic device may also be adapted to use a communication module to report detected radiation to an indicator, a display, and/or a user interface.

While known radiation detectors provide acceptable performance in some scenarios, it would be desirable to provide a radiation detector that reduces or overcomes some or all of the difficulties inherent in prior known devices. Particular objects and advantages will be apparent to those skilled in the art, that is, those who are knowledgeable or experienced in this field of technology, in view of the following disclosure and detailed description of certain embodiments.

### SUMMARY

Systems, methods, and products to address these and other needs are described herein with respect to illustrative, non-limiting, implementations. Various alternatives, modifications and equivalents are possible.

According to a first aspect, a radiation detector is described. The detector includes a silicon photomultiplier (SiPM), a scintillator, and a layer comprising metal that is spaced from the scintillator. The scintillator is arranged to emit light towards the SiPM. The layer comprising metal is configured to receive incident light radiation and to provide additional radiation to the scintillator in response to the received incident radiation.

According to a second aspect, a method of forming a radiation detector is described. The method includes steps of, providing a spacer material, forming an aperture through the spacer material, attaching a layer comprising metal across the aperture of the spacer material, forming a spacer from the spacer material, and attaching the spacer to a substrate having a scintillator and a SiPM thereon. The layer comprising metal is configured to receive incident radiation and to emit additional radiation in response to the received incident radiation. The scintillator and the SiPM are within the aperture and the layer comprising metal is spaced apart from the scintillator.

According to a third aspect, a radiation detector is described. The radiation detector includes a SiPM, a scintillator arranged to emit light towards the SiPM, a casing enclosing the SiPM and the scintillator, and a flat cable extending from outside the casing to inside the casing. The casing comprises a first portion and a second portion parallel to the first portion of the casing. The cable is folded at least once and passes between the first portion of the casing and the second portion of the casing.

The present disclosure provides radiation detectors that have good performance across a wide range of energies and methods for making such detectors. The radiation detectors disclosed herein may have relatively small form factors, allowing them to be used in a variety of scenarios. Some implementations of the radiation detectors include metals that create additional radiation, to improve the performance of photomultipliers. Other implementations include structures that support such metals in advantageous locations, spaced apart from other components. Yet further implementations relate to the way in which pressure inside a detector can be held at an appropriate level, to improve calibration. Moreover, some implementations provide detectors that have sealed casings, and which provide advantageous ways of feeding cable into such sealed casings, with labyrinth-like structures.

These and other advantages will become apparent from the following detailed description and the accompanying figures.

### BRIEF DESCRIPTION OF THE DRAWINGS

The foregoing and other features and advantages of the present implementations will be more fully understood from the following detailed description of illustrative implementations taken in conjunction with the accompanying drawings.

FIG. 1 shows a radiation detector, according to some implementations.

FIG. 2 shows a radiation detector, according to some implementations.

FIG. 3 shows a spacer for a radiation detector.

FIG. 4 shows the way in which radiation interacts with materials.

FIG. 5 shows the excitation profile of Nickel.

FIG. 6 shows the effects of adding a Nickel layer to a radiation detector.

FIG. 7A to 7J show a method of forming a radiation detector.

FIG. 8 shows the result of the method of FIG. 7.

FIG. 9 a practical implementation of two radiation detectors for measuring gamma and/or beta radiation.

FIG. 10 shows a radiation detector, according to some implementations.

FIG. 11 shows a radiation detector, according to some implementations.

The figures referred to above are not drawn necessarily to scale, should be understood to provide a representation of particular embodiments, and are merely conceptual in nature and illustrative of the principals involved. The same reference numbers are used in the drawings for similar or identical components and features shown in various alternative embodiments.

### DETAILED DESCRIPTION

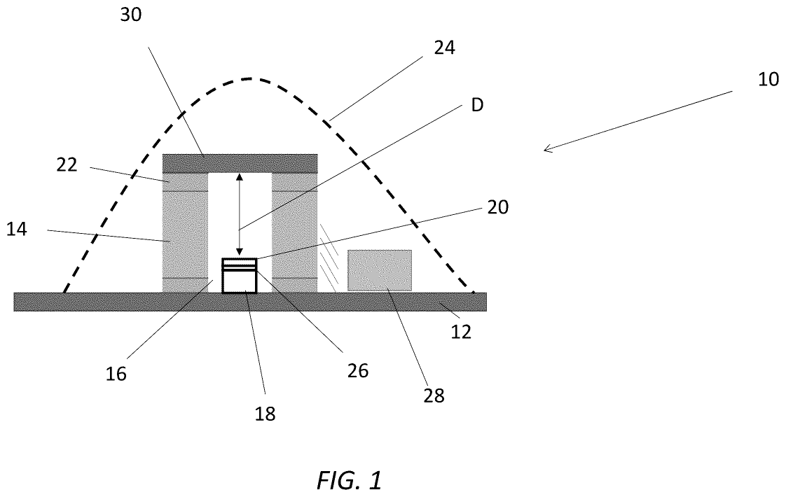

Referring to FIG. 1, a radiation detector 10 includes a substrate 12, which in this particular implementation is a printed circuit board, although other substrates could be used (e.g. a non-printed circuit board). The substrate 12 may house various electronic components including, for example, a temperature sensor (not shown), a microcontroller (not shown), an amplifier (not shown), a bias generator (not shown), and comparators (not shown). Such components may operate in the manner described in US-2021/278550A1, which is incorporated herein by reference. Other suitable components for the printed circuit board 12 will become readily apparent to those of skill in the art, given the benefit of this disclosure.

A photomultiplier 18 and a scintillator 20 are operably connected to printed circuit board 12 in a known fashion. The printed circuit board 12 includes a cable (not shown), which may be, for example, a flat cable that serves to provide power and/or data transmission to and from the printed circuit board 12. The cable may provide digital data communication with the printed circuit board 12 via UART, SPI, or I2C, for example. In some alternate implementations, the cable may be a board-to-board connector of known construction.

The radiation detector 10 includes a photomultiplier 18 that is on the printed circuit board 12 and operably connected to the printed circuit board 12. In certain implementations, the photomultiplier 18 may be a Silicon (Si) photomultiplier.

A scintillator 20 that is sensitive to gamma and/or beta radiation in the form of a coating is directly applied to an upper surface of the photomultiplier 18. In certain implementations, the scintillator 20 comprises an organic scintillator material applied as a coating, such as for example a coating of doped polyvinyl toluene (PVT). Exemplary doped PVT products include BC-400 and BC-404 provided by Saint-Gobain Crystals of Hiram, Ohio; and EJ-296 provided by Eljen Technology of Sweetwater, Texas. It is to be appreciated that the scintillator 20 may also contain xylene.

Due to the light sensitivity of the photomultiplier 18, the region around the photomultiplier 18 is preferably light sealed to prevent ambient light from affecting the performance of the detector 10. A casing 24 is secured to an upper surface of the substrate 12 and extends around a periphery of the photomultiplier 18 and the scintillator 20. It is to be appreciated that in certain implementations, the casing 24 can be secured to the printed circuit board 12 in such a manner so as to completely cover the entirety of the printed circuit board 12. However, in some implementations the casing 24 may include a thin “entry window” constructed from metallised mylar, thin metal foil, or other similar materials, where the entry window also has a dimension and orientation to permit gamma and beta radiation to pass. The casing 24 may be formed of black tape, aluminium tape, or copper tape, for example. In some implementations, the casing 24 may be wrapped around the substrate 12 and the various other components of the radiation detector 10.

Within the casing 24, a light emitting device 28 is provided. The light emitting device 28 may be, for example, a light emitting diode (LED), or another light source. The light emitting device 28 may be used for calibration of the radiation detector 10 or for a detector and signal chain self-test. That is, photons emitted by the light emitting device 28 may have a known energy and/or wavelength and so may be used to calibrate measurements obtained by the radiation detector 10.

In some implementations, the photomultiplier 18 has a width of approximately 1 mm and a length of approximately 1 mm. However, the surface area of the photomultiplier 18 can be increased to achieve more detector sensitivity or the surface area can be decreased to provide more compact detector assemblies. The scintillator 20 and photomultiplier 18 may together have a height of between approximately 1 mm and approximately 5 mm, a length of between approximately 10 mm and approximately 25 mm, and a depth (not shown here) of between approximately 10 mm and approximately 25 mm. Thus, such a detector assembly provides a compact form factor that can be adapted to various use cases. An example of a suitable photomultiplier is the SiPM MicroFC10035.

The scintillator 20 may be attached to the photomultiplier 18 by means of a glue 26. In some implementation, the optical glue 26 has a similar refraction index to the scintillator. For example, in some implementations, the optical glue has a refractive index ±20% (e.g., ±10%) the refractive index of the scintillator 20 material. In some implementations the scintillator 20 has a refractive index of about 1.58. In some implementations, the optical glue 26 has a low absorption in the wavelength of the light emitted by the scintillator 20. For example, in some implementations, the optical glue has less that about 5% absorption in the range of 400 nm and 500 nm.

Alternatively, providing the scintillator 20 on the photomultiplier 18 may be performed by another method. An organic scintillator material for forming the scintillator 20 may be combined with a solvent, such as xylene. The combined organic scintillator material for forming the scintillator 20 and the solvent may then be dispensed from the pipette onto a surface of the photomultiplier 18. The photomultiplier 18 and scintillator material may then be heated in a vacuum oven, where the solvent evaporates and the scintillator 20 cures on the photomultiplier 18. In certain implementations, there may be no heating required and the scintillator 20 may be formed by drying at room temperature. It will be appreciated by those skilled in the art, that the shrinkage of the scintillator 20 during the curing cycle will be accounted for to match the desired thickness. The thickness of the scintillator 20 can be varied, for example, by coating the surface of the photomultiplier 18 multiple times. By varying the thickness of the scintillator 20 placed on the photomultiplier 18, the sensitivity of the detector 10 can be varied.

In certain implementations, the scintillator 20 may have a thickness between approximately 100 μm and approximately 1 mm. The surface dimensions depend on the photomultiplier used (which typically have sizes of: 1 mm×1 mm, 3 mm×3 mm, 6 mm×6 mm). In some implementations, a combination uses a 1 mm×1 mm scintillator with a 400 μm thickness. Some photomultipliers, such as SiPMs, have passive areas that are part of the packaging and that do not detect light. Thus, the scintillator may be smaller than the photomultiplier component and may be centered thereon.

The radiation detector 10 works in known fashion to provide light scintillation that can be detected as light pulses from the scintillator 20 in response to gamma and/or beta radiation, which are converted into electrical signals by the photomultiplier 18. FIG. 1 illustrates a radiation detector 10 having only a single scintillator 20 and photomultiplier 18, but it will be appreciated that the radiation detector 10 may include multiple scintillators and photomultipliers, which may be useful for some applications such as the detection of beta radiation.

As described in US-2021/278550A1, which is incorporated herein by reference, the radiation detector 10 may be controlled by a microcontroller positioned on the substrate 12. The radiation detector 10 may also include a capacitive filter to suppress electromagnetic interference and electrostatic discharge. As noted above, the radiation detector 10 may include a temperature sensor. A bias voltage generator may provide a voltage (e.g. 32 V) to the detector assembly, and a reference voltage for a threshold voltage generator. A threshold voltage generator may have four channels to provide four reference signals. Comparators may then be used to compare the reference signals from the threshold voltage generator with the signals from the four channels from the scintillator and photomultiplier, and the pulse shapes of the signals may be compared to generate the signals based on the gamma rays detected.

One implementation of the present disclosure recognises that the performance of a radiation detector 10 can be improved by providing a thin layer 30 comprising certain types of metal (e.g. nickel) at a certain distance D from the scintillator. In particular, and as will be described in further detail below, layers of certain metals can be used to enhance the performance of the radiation detector 10. The layer 30 may absorb certain radiation and re-emit photons in certain energy ranges. Such an effect may serve to improve the sensitivity of the radiation detector 10 in certain energy ranges, by increasing the magnitude of the signal in those ranges. In effect, the layer 30 may “boost” the measured signal. This effect may be particularly pronounced when the scintillator is an organic scintillator or a plastic scintillator. However, non-organic doped plastic scintillators can also be used.

In FIG. 1, a layer 30 comprising nickel is provided at a distance D from the scintillator 20. D in some implementations is from 50 μm to 1000 μm, but various other distances can be used. The layer 30 is substantially parallel to the upper surface of the scintillator 20 and to the substrate 12. The layer 30 is held in position by a spacer 14, which is shown as being a solid body having an aperture therethrough. The layer 30 is held in position by an adhesive 22, which holds the layer 30 to the spacer 14. The aperture through the body of the spacer 14 defines a chamber 16, in which the scintillator 20 and the photomultiplier 18 are located. The radiation detector is devoid of radiation absorbing material (e.g. solid material) between (i.e. directly between) the layer comprising metal and the scintillator. For example, ambient air may be in the aperture between the layer comprising metal and the scintillator.

The radiation detector 10 of FIG. 1 is primarily used for detection of photons and provides a compact design with good performance. However, other radiation can be detected.

The layer comprising metal is particularly advantageous when used in combination with a plastic scintillator and can make dose rate calculations more straightforward. Plastic scintillators typically have low density and provide relatively poor performance at low energies. The layer comprising metal may act as a structure that boosts low-energy radiation through the use of, for example, a Ni thin film. Such a film may not absorb radiation, but instead, radiation may interact with the film and give additional electrons that the plastic scintillator is arranged to receive. Thus, improvements can be obtained from the combination of Ni (or other appropriate substances) together with a plastic scintillator (or any other scintillator having relatively poor performance at low energies). If a scintillator is too close to a reflective surface, then these beneficial effects may become less pronounced, so a certain level of spacing is preferably provided between the layer comprising metal and the scintillator. Thus, the spacers described herein may help to achieve appropriate spacing. The spacers may be described as doughnut-shaped and may be made from plastic and/or be partially transparent. A typical distance between the layer comprising metal and the scintillator is ˜200 microns, although other distances can be used.

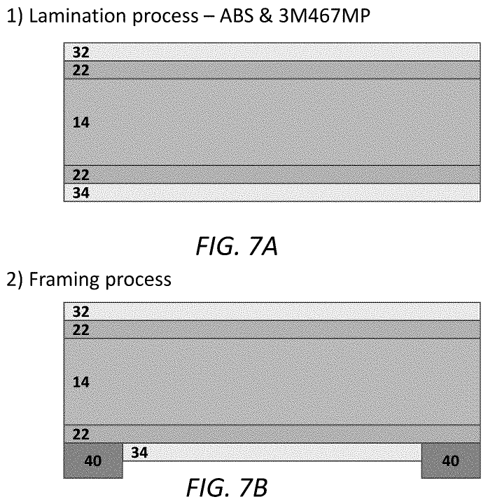

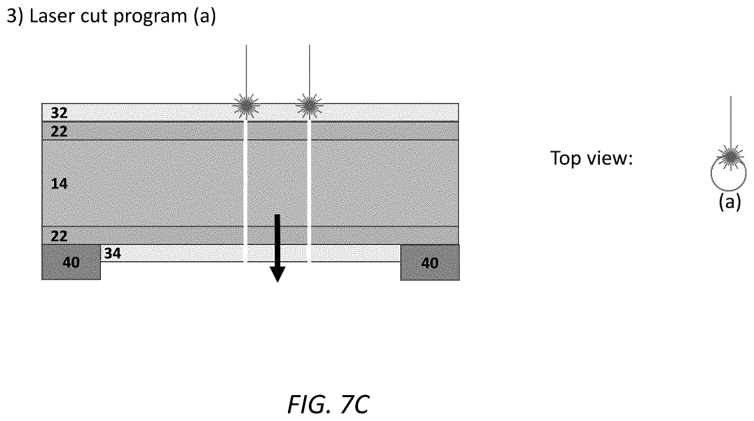

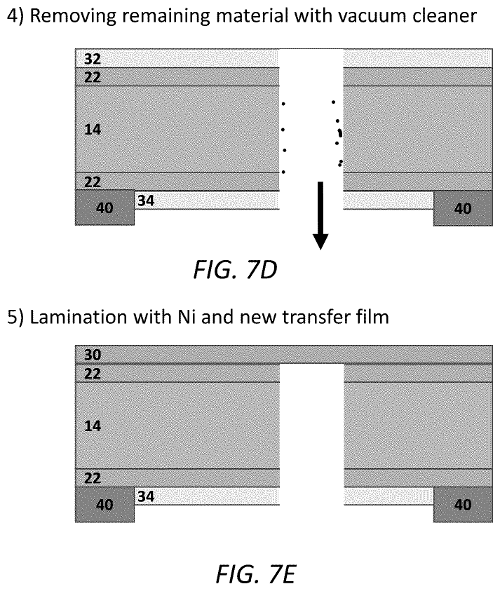

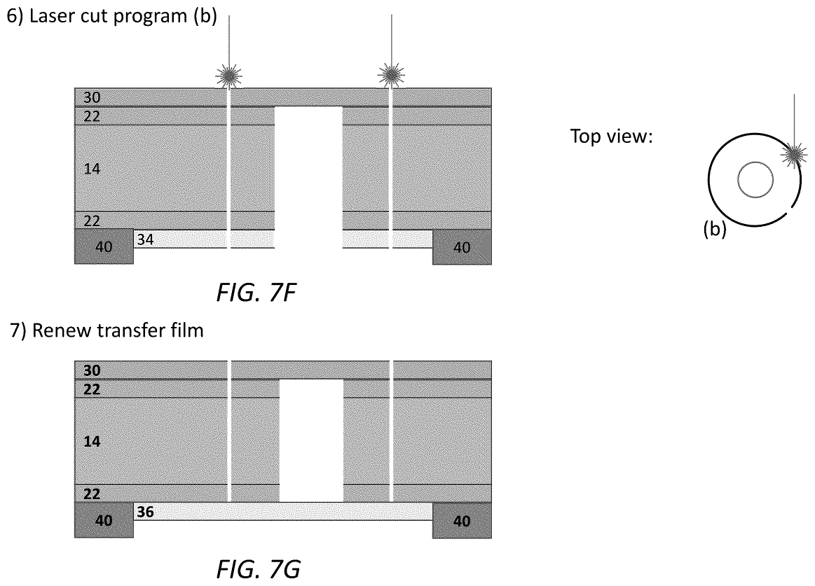

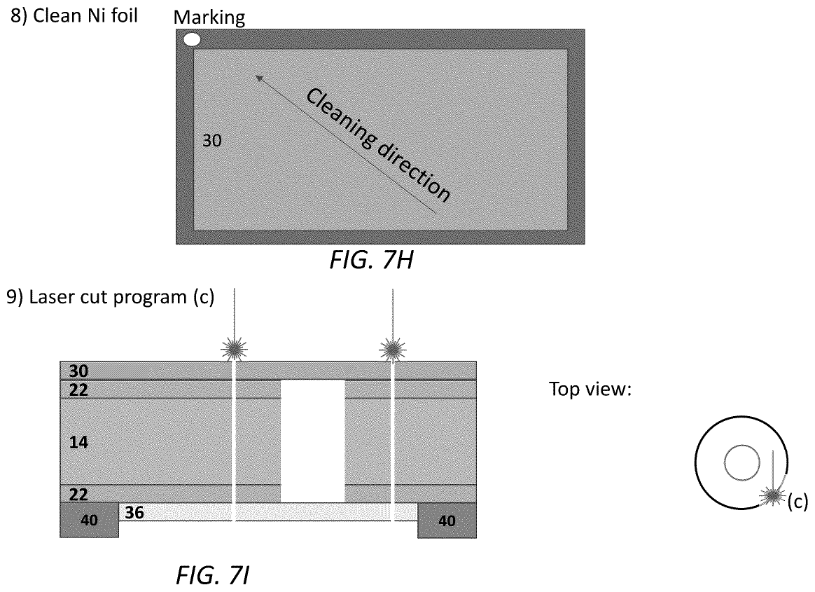

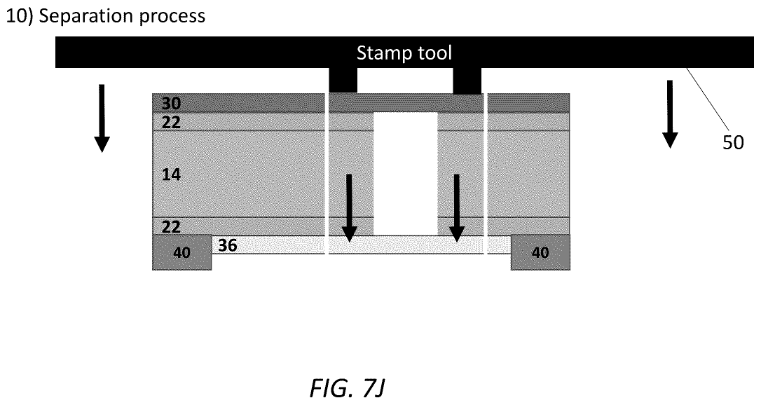

The spacers described herein can have various forms. Preferably, the spacers are at least partially transparent so that the material allows the light from light emitting device 28 (e.g. LED) for self-testing to shine through. As will be explained in further detail subsequently (in relation to FIG. 7A to 7J), various materials can be used. In some implementations, materials capable of being cut by laser are selected.

FIG. 1 is a specific example of an advantageous implementation of the present invention. However, it will be appreciated that the general principles of the device of FIG. 1 are more generally applicable. For example, in a general sense, the present disclosure advantageously provides a radiation detector comprising: a SiPM; a scintillator arranged to emit light towards the SiPM; and a layer comprising metal that is spaced apart from the scintillator, wherein the layer comprising metal is configured to receive (e.g. absorb, or scatter) incident radiation and to provide additional radiation to the scintillator. By providing a radiation detector having such a layer comprising metal, the performance of the radiation detector can be improved.

In some implementations, the layer comprising metal comprises nickel. However, other materials can be used to advantageous effect. The layer comprising metal may comprise a metal having an atomic number (Z) of at least 15, at least 20, or at least 25. The layer comprising metal may comprise a mixture of metals, such as a blend of multiple metals on a substrate. For instance, the layer comprising metal may comprise mylar and, optionally, the metal of the layer comprising metal may be sputtered on the mylar or deposited on mylar in any other way. The layer comprising metal is preferably a thin film. Suitable thicknesses include greater than or equal to 1×10⁻⁶ m; greater than or equal to 2×10⁻⁶ m; greater than or equal to 3×10⁻⁶ m; less than or equal to 10×10⁻⁶ m; less than or equal to 20×10⁻⁶ m; or less than or equal to 30×10⁻⁶ m. The layer comprising metal is preferably (at least partially) optically reflective. For instance, the layer may reflect at least 90%, at least 95%, or at least 99% of light incident thereon. This may improve performance of the detector by ensuring that light is not directed away from the photomultiplier.

In some implementations, a distance D between the layer comprising metal and the scintillator is: greater than or equal to 50×10⁻⁶ m; greater than or equal to 200×10⁻⁶ m; greater than or equal to 500×10⁻⁶ m; less than or equal to 750×10⁻⁶ m; less than or equal to 1000×10⁻⁶ m; or less than or equal to 1500×10⁻⁶ m. Such distances provide good performance.

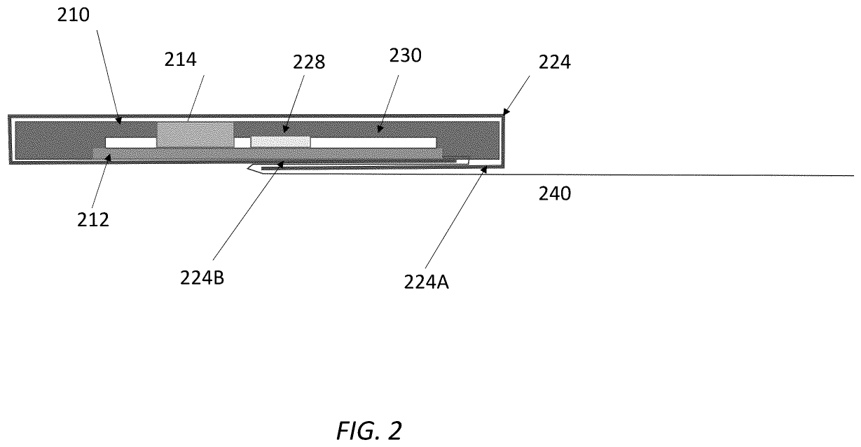

Another implementation of a radiation detector 210 is shown in FIG. 2. The radiation detector 210 of FIG. 2 works according to the same principles as radiation detector 10 of FIG. 1. FIG. 2 shows how to encapsulate a detector in a cost-optimized way, by wrapping with a tape (e.g. an aluminum tape, which may have adhesive tape included).

This implementation also comprises a spacer 214 as described previously, which holds a layer comprising metal at a distance from the substrate 212, which has a light emitting device 228 disposed thereon. In this implementation, the casing 24 (FIG. 1) is replaced by a casing 224 that has a different form. In this implementation, a casing 224 surrounds the radiation detector 210. In certain implementations, the casing 224 may be formed of metal, such as aluminium, for example. The entirety of the radiation detector 210 may thus be encased within the casing 224, thereby preventing ambient light from affecting the performance of the radiation detector 210. The casing 224 may also be constructed to filter beta radiation, which can also be detected by the radiation detector 210, as well as provide electromagnetic interference (EMI) shielding. Some implementations may also include an energy filter constructed of plastic (e.g. 2-3 mm thick) that filters beta radiation. A flat cable 240 is used to provide a way of reading signals from the internal electronics of the radiation detector 210. The flat cable 240 provides a particularly advantageous mechanism for connecting to the radiation detector 210.

The casing 224 encapsulates the radiation detector 210 and the cable 240 provides a connection to external components (e.g. devices for reading data from the radiation detector 210). Also shown in FIG. 2 is a detector holder 230, which comprises black plastic.

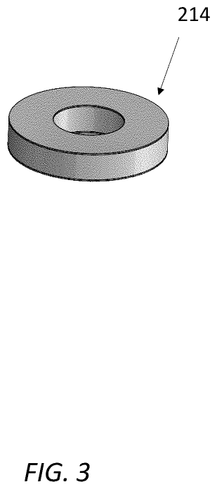

FIG. 3 shows the spacer 14 of FIG. 1 in more detail. The spacer 14 has a generally cylindrical form with a cylindrical aperture through it. Hence, the spacer may be described as “doughnut”-shaped. The spacer 14 may be formed of a transparent material, such as acrylonitrile butadiene styrene (ABS), for instance, to allow the light emitting device 28 to provide testing functionality. The spacer in 214 in FIG. 2 may be substantially the same as the spacer in FIGS. 1 and 3.

In a general sense, the spacers described herein may be arranged to hold the layer comprising metal in a position that that is spaced apart from the scintillator. The spacing can be as described previously. In some implementations, the spacer comprises an aperture. In this way, the spacer can surround components within the aperture. The aperture extends between a first surface of the spacer that is adjacent to the SiPM (e.g. a bottom surface) and a second surface of the spacer that is adjacent to the layer comprising metal (e.g. a top surface). For instance, one end of the spacer may be attached to a substrate on which a SiPM is mounted, and the aperture may extend between the surface that is closest to the substrate and the top surface of the spacer, on which the layer comprising metal is disposed. The aperture is preferably cylindrical, and an outer surface of the spacer is preferably cylindrical. These shapes are relatively efficient to manufacture, although other shapes can be used. In use, the scintillator and/or the SiPM may be within the aperture of the spacer.

The spacers described herein can be formed from various materials. In some implementations, the material for the spacer comprises white acrylonitrile butadiene styrene (ABS). It is also advantageous for the spacer to be (at least partially) optically transparent (e.g. allowing up to 5% of light through). For instance, such transparency may allow a self-test light emitting device, such as 28 and 228 (FIGS. 1 and 2) that is mounted outside the spacer to provide light to the SiPM. That is, in cases where the radiation detectors comprise a light emitting device for testing the radiation detector, the spacer may be arranged to hold the layer comprising metal in a position that that is spaced apart from the scintillator, and the light emitting device may be arranged to emit light through the spacer and towards the scintillator and/or the SiPM. This can allow the radiation detector to automatically test and/or calibrate itself. The light emitting device may comprise a light emitting diode (LED), which can have a known wavelength, thus allowing calibration.

As shown in FIG. 2, a radiation detector may advantageously be encapsulated to prevent light entering the detector. Thus, in general terms, the radiation detectors of the present disclosure may comprise the casing 224 enclosing (e.g. encapsulating, in a light-tight manner) the SiPM, the scintillator and the layer comprising metal. This can prevent the components of the detector from interference from outside light. The casing 224 may be opaque to prevent ingress of light. The casing 224 may be optically reflective, for example on the interior surface. This may improve the efficiency of the detector. The casing 224 may comprise aluminium, which could be provided in the form of a film or as aluminium tape. Other materials may be used.

As shown in FIG. 2, the cable 240 needs to pass through the casing 224, which can be difficult to achieve particularly when the casing 224 is wrapped around the detector. It should be noted that it is not essential for such a cable to be provided, since a wireless module in the detector could instead provide wireless communication to outside the detector and the detector may have an internal power supply. However, in general terms, implementations of the present disclosure may comprise a cable extending from outside the casing 224 to inside the casing 224. The cable 240 may be a power and/or data communication cable, to provide power to the detector and/or to allow data from the detector to be read. The cable 224 provides a connection to the SiPM, for example to read data therefrom.

In preferred implementations, the cable 240 is a flat cable. This may mean that the width of the cable 240 is much greater than the thickness (e.g. at least twice as wide, or at least 5 times as wide, or at least 10 times as wide). That is, a ratio of the thickness of the cable 240 to the width of the cable 240 may be 1:2, 1:5, 1:10, or 1:25 or even higher. The cable 240 may have a meandering structure, with one or more bends, to permit the cable 240 to pass through intricate structures. To that end, the cable 240 may be flexible.

The casing 224 of the detectors described herein may comprise a first portion and a second portion parallel to the first portion, and the cable 240 may pass between the first portion of the casing 224 and the second portion of the casing 224. For instance, the casing 224 may be wrapped around the radiation detector 210, and the first and second portions of the casing 224 may be overlapping. The first and second portions of the casing 224 may be adhered (e.g. glued or bonded in some way) to each other.

The casing 224 may provide a light-tight structure. However, it can be difficult to provide a connection into the casing 224. Thus, the meandering cable 240 structures described above may be advantageous. For example, the cable 240 may extend along a first surface of the first portion of the casing 224 (e.g. the outside of surface 224A in FIG. 2). The cable 240 may extend along a second surface of the first portion of the casing 224 (e.g. the inside of surface 224A in FIG. 2) and a first surface of the second portion of the casing (e.g. the outside of surface 224B in FIG. 2). Additionally, the cable 240 may extend along a second surface of the second portion of the casing (e.g. the inside of surface 224B in FIG. 2). Hence, in generalised terms, the first surface of the first portion of the casing may be an exterior surface and the second surface of the first portion of the casing may be an interior surface; and/or the first surface of the second portion of the casing may be an exterior surface and the second surface of the second portion of the casing may be an interior surface. Thus, to pass through such a structure, the cable may comprise three (or more) flat portions that are mutually parallel (i.e. the first portion is parallel to the second and third portions, which are also parallel to each other). Moreover, the cable may be folded (e.g. with 180° bends) at least once and preferably at least twice.

It will be appreciated that this cable and casing structure is generally applicable and does not need to be used in conjunction with a layer comprising metal or a spacer. Any encapsulated detector can benefit from this way of leading into a detector. Thus, the disclosure also provides, in generalise terms, a radiation detector comprising: a SiPM; a scintillator arranged to emit light towards the SiPM; a casing enclosing the SiPM and the scintillator, wherein the casing comprises a first portion and a second portion parallel to the first portion of the casing; and a flat cable extending from outside the casing to inside the casing, wherein the cable is folded at least once and passes between the first portion of the casing and the second portion of the casing. This provides a convenient way of providing a light-tight casing while still permitting data readout and/or providing power.

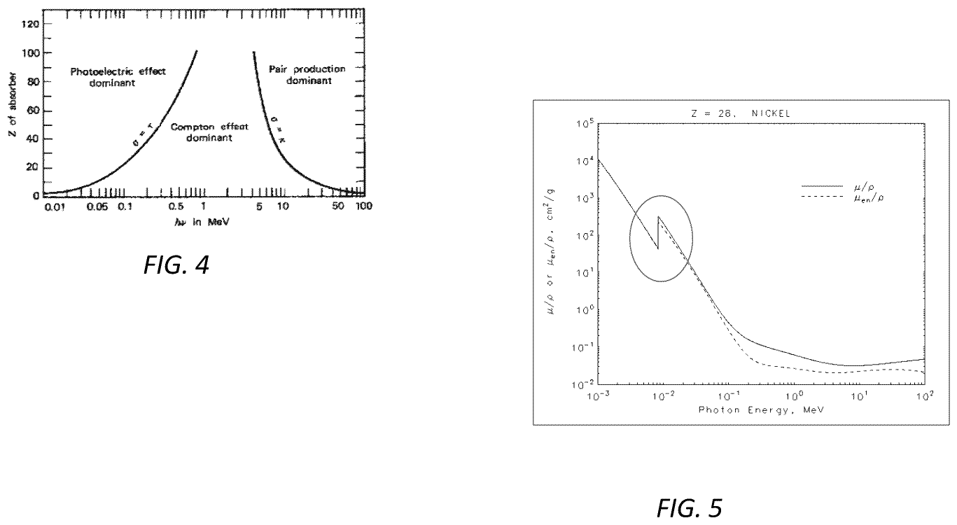

It will be appreciated that the layer comprising metal in FIG. 1 is an advantageous feature of the present disclosure. Without wishing to be bound by theory, it is thought that, as shown in FIGS. 4 and 5, the basic physical effects behind the “generation of electrons” provided by the layer 30 comprising metal are the photoelectric effect and the Compton effect (see FIG. 5, from Knoll (2010)). One advantage of nickel is that it has good optical reflection characteristics. In addition to the primary interaction of gamma radiation with the detector scintillator, the additional electrons (provided by the layer 30 comprising metal) occur especially in the excitation energy range of the marked peak in FIG. 5. This position varies from material to material and the electron support supports the target energy response. The impact also depends on the scintillator sensitivity on electrons (beta radiation sensitivity). Hence, in a general sense, in implementations of the present disclosure, the layer comprising metal may be configured to emit additional radiation that is provided to the scintillator by the photoelectric effect and/or the Compton effect.

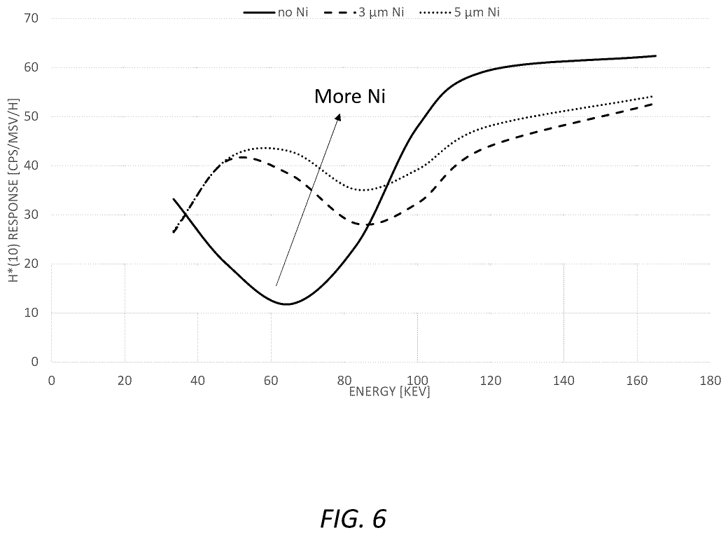

FIG. 6 shows the effect on adding a layer comprising nickel to a radiation detector. As the nickel content of the layer increases, the response at low energies is improved, improving the useability of the detector at those energies. Thus, in a general sense, the layers comprising metal of the present disclosure can be advantageous due to the SiPM having a relatively low response for a first range of light energies (e.g. at low energies) and a relatively high response for a second range of light energies (e.g. at higher energies); and the layer comprising metal being configured to provide, to the scintillator, additional radiation having energies to cause the scintillator to emit, to the SiPM, light in the first range of light energies. Such a layer can improve performance in the first range of light energies. The first range of light energies is preferably lower than the second range of light energies and the ranges should be non-overlapping. The layer comprising metal may be arranged to receive incident radiation (e.g. photons) and to provide additional radiation (e.g. electrons) to the scintillator to increase the light emitted towards the SiPM (relative to the amount of radiation that would be provided to the SiPM in the absence of the layer comprising metal).

While the layer 30 (FIG. 1) comprising metal has been described with reference to nickel, other materials can also work. The atomic number, Z, is an important factor and should be at least approximately 15, since materials with low Z (e.g. aluminium) do not provide the desired effect. Advantageously, nickel is readily available in very thin thicknesses of a few microns. In the implementation shown in FIG. 1, nickel foil having a thickness of 2.5 μm is used. However, all materials that can be rolled thin or be sputtered on a thin plastic foil (e.g. mylar foil) are in general possible for this application. Depending on the density of the material, thicker layers may be less beneficial because of absorption of the primary radiation spectrum and self-absorption of the generated electrons. In implementations of the present disclosure, pure nickel provides adequate results, but even better results may be possible, for example by using specific mixtures of materials.

Turning next to FIG. 7, which comprises sub-FIG. 7A to 7J, a method for making a part of a radiation detector is shown by a lamination process. The method comprises 10 steps.

FIG. 7A shows a spacer material 14, which is white ABS, with adhesive 22 (e.g. 3M467MP double-sided tape-3M Co, St Paul, MN) thereon, and transfer films 32 and 34 on the adhesive 22. In FIG. 7B, a frame 40 is provided.

FIG. 7C shows a first step of cutting through the spacer material 14. The transfer film 32, the adhesive 22, the spacer material 14 and the transfer film 34 are all cut simultaneously. A circular (although other shapes could be used) laser cut is performed.

The cutting illustrated by FIG. 7C forms an aperture in the spacer 14. In FIG. 7D, the remaining material is removed by a vacuum cleaner.

Then, as shown in FIG. 7E, a layer 30 comprising metal is added, which in this case is Ni. A new transfer film 34 is added. To do so, Ni foil may first be placed on a flat surface and release paper may be cleaned. Then, a low amount of isopropanol may be put on the foil. Then, using a microfiber towel, the foil can be pressed onto the surface of the adhesive 22 until all warps/wrinkles are removed. It is important to wrap the laminate over one edge to the Ni-foil.

As illustrated in FIG. 7F, a second laser cut is performed. This laser cut simultaneously cuts through the layer 30 comprising metal, the adhesive 22, the spacer material 14 and the transfer film 34. This laser cut does not fully separate a spacer from the spacer material. As shown in the top view, the laser traces almost a full circle, but leaves a small portion of the circle uncut. This attachment ensures that the stack of layers stays together and does not separate.

As illustrated in FIG. 7G, the transfer film 34 shown in FIG. 7F (which was cut in the previous step) is removed and replaced with a new transfer film, 36.

In FIG. 7H, the layer 30 comprising metal is cleaned. The cleaning direction is shown. The cleaning direction avoids pealing off of the layer 30 since, as described, the laser cut leaves a small portion of the circle uncut, and the cleaning direction is selected to avoid lifting off the layer 30.

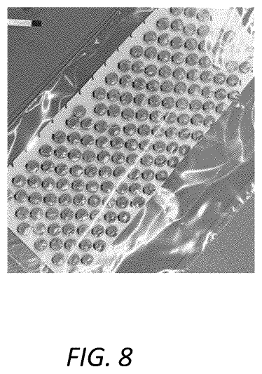

Turning to FIG. 7I, a third laser cut is performed. This simultaneously cuts through the layer 30 comprising metal, the adhesives 22, the spacer material 14 and the replacement transfer film 36. This completes the partial cut shown in step 6 in FIG. 7F. As shown in FIG. 7J, an assembly comprising a transfer film 36, adhesive 22, spacer material 14 (which is now a fully-formed spacer) and the layer 30 comprising metal can then be pushed out from the raw material with a stamp tool 50. A collection of products that result from the method of FIG. 7A-7J is shown in FIG. 8. Such products can be applied to a substrate, such as a PCB, to provide a structure of the type shown in FIGS. 1 and 2. For example, the transfer film 36 can be removed to expose the adhesive 22, following which the assembly can be attached to a substrate. Thus, this method provides a convenient and efficient way for providing an assembly that can be used to improve the performance of a radiation detector.

As mentioned previously, the present disclosure provides specific examples of radiation detectors and methods that can be applied more generally than the specific examples shown. Thus, returning to the general terms used previously, the disclosure also provides a method of forming a radiation detector, the method comprising steps of: providing a spacer material; forming an aperture through the spacer material (e.g. as shown in FIG. 7C); attaching a layer comprising metal across the aperture of the spacer material (e.g. as shown in FIG. 7E), wherein the layer comprising metal is configured to receive incident radiation and to emit additional radiation (e.g. towards the scintillator and/or photomultiplier of the detector); forming a spacer from the spacer material (e.g. as shown in FIG. 7F to 7J), the spacer comprising the aperture. The method may further comprise attaching the spacer to a substrate having a scintillator and a SiPM thereon, such that the scintillator and the SiPM are within the aperture and the layer comprising metal is spaced apart from the scintillator. However, the method could be truncated before this final step of attaching the spacer to a substrate, to provide a spacer assembly that can be provided as a standalone product that can be fitted to a substrate to improve the performance of an existing detector.

The layer 30 comprising metal may be attached using an adhesive (e.g. 22 in FIG. 7A to 7J). The spacer (e.g., 214 FIG. 3) may have adhesive on an opposite surface to permit the spacer to be attached to the substrate (e.g., 212 FIG. 2). The aperture may extend between first and second surfaces of the spacer material, the method further comprising applying first and second adhesives to the first and second surfaces (e.g. opposing surfaces, such as top and bottom) of the spacer material.

A transfer film (or multiple transfer films) may be attached to at least one of the first and/or second adhesives. Such transfer films may prevent the adhesive from being spoiled. The method may thus comprise removing at least one transfer film before attaching the layer comprising metal across the aperture (for example as shown in FIG. 7E). The adhesive may comprise double-sided tape of various kinds.

The method may provide a laminated structure. Forming the aperture may comprise cutting the spacer material (and optionally any other layers attached thereto, such as transfer film and/or adhesive), preferably by laser cutting, for example as shown in FIGS. 7C and 7D. Forming the aperture may comprise simultaneously cutting the spacer material, the adhesive and/or the transfer film, preferably by laser cutting.

Forming the spacer may comprise removing a portion of the spacer material around the aperture (e.g. cutting a spacer from the raw material, the spacer including the aperture and a wall surrounding the aperture) and removing a portion of the layer comprising metal on the portion of the spacer material around the aperture (e.g. the portion of the layer that sits across the top of the aperture may be retained), for example by laser cutting. Removing the portion of the spacer material around the aperture may occur simultaneously with removing the portion of the layer comprising metal (e.g. they may be laser cut simultaneously). Removing the portion of the spacer material around the aperture may occur simultaneously with removing a portion of transfer film attached to the spacer material (since the transfer film may also be laser cut). Removing the portion of the spacer material around the aperture and the portion of the layer comprising metal may comprise cutting or laser cutting the spacer material and the layer comprising metal. Removing the portion of the spacer material around the aperture and removing the portion of the layer comprising metal may occur simultaneously with removing a portion of transfer film attached to the spacer material. Again, this may be performed by laser cutting. However, other techniques, such as milling or grinding, could be used. An example of such a process in shown in FIG. 7F to 7I.

The method may comprise replacing the transfer film with a replacement transfer film, for example as shown in FIG. 7E or in 7G. Forming the spacer may comprise cutting the replacement transfer film to separate the layer comprising metal, the spacer and the replacement transfer film from the portion of the spacer material. This is shown in FIG. 7I.

To reliably provide a convenient spacer assembly that can be attached to a substrate, it is preferable for the spacer to be on a fresh transfer film. Accordingly, the method may comprise partially cutting the layer comprising metal (e.g. by cutting only a portion of the aperture, as shown in FIG. 7F), the spacer and the transfer film; replacing the transfer film with a replacement transfer film (as shown in FIG. 7G); and completing cutting the layer comprising metal, the spacer and the transfer film (as shown in FIG. 7I). The step of partially cutting can help to ensure that the assembly of the spacer and layer comprising metal does not fall apart while the new transfer film is being provided.

Once the spacer assembly has been formed, the method may comprise removing the spacer from the spacer material by pressing the spacer from the spacer material, as shown in, for example FIG. 7J. The spacer material to the substrate using an adhesive, such as the double-sided tape provided on the bottom of the spacer and underneath the transfer film. Such a method can be used to for making any of the radiation detectors described herein.

The results of such a method are shown in FIG. 8. It can be seen in FIG. 8 that the nickel layers can become wrinkled. If the nickel foil is slightly wrinkled, then it is more difficult to calibrate the detector. Calibration is more straightforward if the nickel foil is flat. Thus, it may be advantageous to reduce the risk of the layer comprising metal (e.g. foil) changing shape as the pressure changes, by equalising the pressure inside the layer with the pressure outside the layer. This can be achieved by providing a channel to allow gas exchange. This could be provided by not fully adhering the foil to the detector (e.g. by leaving a gap in glue) or by drilling a hole in the device, for example in the substrate. Thus, ambient air can move from inside the chamber of the detector and a more reliable device that does not lose its calibration can be provided. For example, in a general sense, the SiPM may be on (e.g. directly on, or indirectly on, i.e. mounted with intervening components) the substrate. The substrate and the layer comprising metal may define a chamber (which may be further defined by the surfaces of the spacer, i.e. the interior walls of the aperture of the spacer may be surfaces of the chamber) and the scintillator and/or the SiPM may be within the chamber, with the chamber comprising an opening for allowing air (e.g. ambient air) into and/or out of the chamber. In some implementations, such an opening is in the substrate, such as a hole drilled through the substrate. However, other openings can be provided.

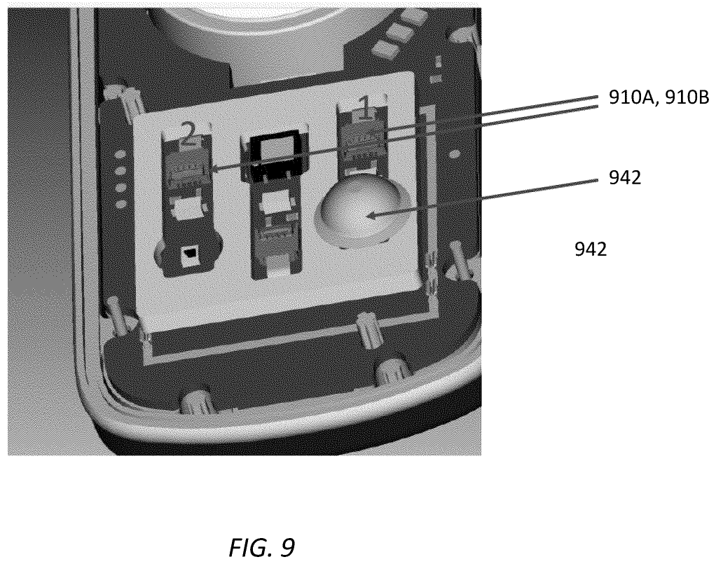

In FIG. 9, there is shown an example of how the radiation detectors described herein can be used. Two fully identical SiPM detector units 910A and 910B are shown. A beta radiation absorber 942 is also provided, which may be a plastic part with metal foil on the rear side. The signals on 1 and 2 are identical for gamma radiation.

Beta radiation=Signal 2−Signal 1

Gamma radiation=Signal 1

Thus, the detectors described herein can be used for the detection of various types of radiation.

As mentioned previously, the detectors described herein may be encapsulated. The detectors described herein provide numerous advantages. They can be suitable for mass production due to a layered foil design, they can be manufactured to be extremely thin, an EMI cage can serve as stabilisation for Ti foil, the detectors can be beta transparent, and energy filtering over angle can be provided.

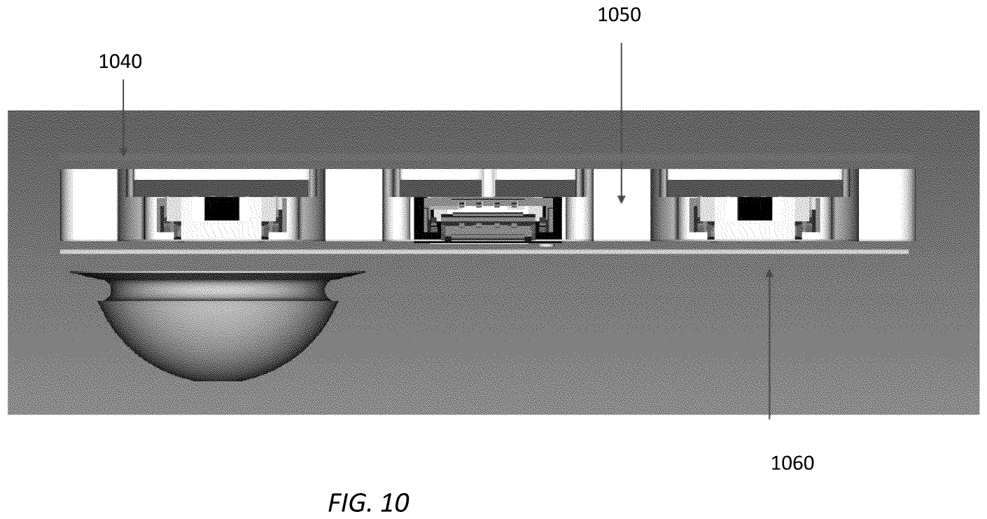

FIG. 10 shows an aluminium foil 1040 (which can be described as a “labyrinth”) with a cable lead through, a black plastic holder 1050, and a Ti foil 1060. FIG. 10 works according to the same principles as FIGS. 1 and 2.

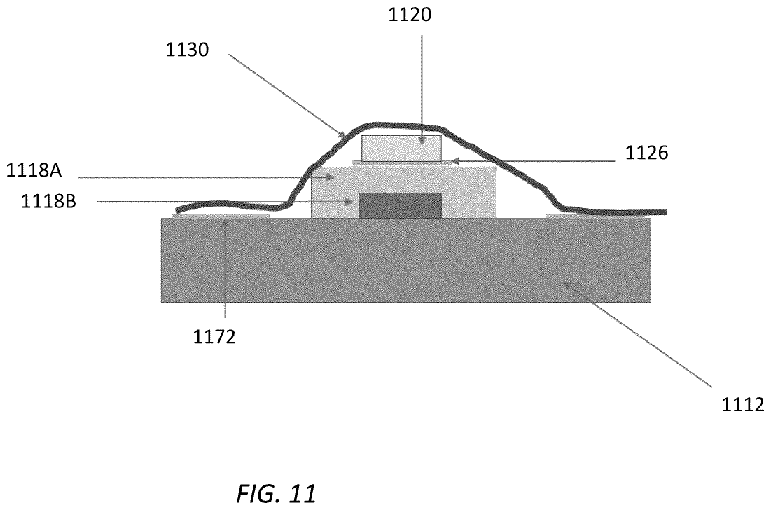

Turning next to FIG. 11, a further implementation is shown. This implementation can detect gamma and beta radiation. FIG. 11 works according to the same principles as FIGS. 1, 2 and 10. As mentioned previously, one unit can be used for gamma-only detection while for gamma-beta detection, two such units are required. This implementation is similar to previous implementations, but does not include a spacer. This implementation includes a substrate 1112, which is again a PCB. Double sided tape 1172 holds a layer comprising metal 1130 to the substrate 1112. The layer comprising metal includes a 10-micron thick foil sandwich (mylar+Ni+Al coated mylar, although alternative solutions for Ni can be provided, e.g. copper). Within the layer 1130, a scintillator 1120 (e.g. a PVT scintillator) is held by an adhesive 1126 to the photomultiplier 1118. The photomultiplier is a SiPM that includes an active part 1118B and a housing 1118A. As described previously, some SiPMs have passive areas, which are part of the packaging and do not detect light. Thus, the scintillator 1120 is smaller than the passive area of the photomultiplier 1118A and is centred thereon. As described previously, the adhesive 1126 should be optical glue with similar refraction index as the scintillator 1120 and a low absorption in the wavelength of the emitted scintillator light.

Various types of scintillator and photomultipliers can be used. Returning to the general terms used previously, the scintillator may be an organic scintillator, a plastic scintillator and the scintillator may comprise polyvinyltoluene (PVT). Various other materials can be used. The scintillator is preferably between the layer comprising metal and the SiPM and preferably on (e.g. mounted on) the SiPM, for example by being adhered (e.g. glued) to the SiPM. Such adhesion may be provided by a glue that is transparent (e.g. at least 90% transparent, or at least 95% transparent, or at least 99% transparent) to the light (e.g. the particular wavelengths) emitted by the scintillator. The SiPM may be on the substrate, and the layer comprising metal and the substrate may surround (together with the spacer, i.e. the layer comprising metal, the spacer and the substrate may collectively encapsulate the SiPM and the scintillator) the SiPM and the scintillator.

The following numbered paragraphs 1-96 provide various examples of the implementations disclosed herein.

1. A radiation detector comprising: a silicon photomultiplier (SiPM); a scintillator arranged to emit light towards the SiPM; and a layer comprising metal that is spaced apart from the scintillator, wherein the layer comprising metal is configured to receive incident radiation and to provide additional radiation to the scintillator in response to the received incident radiation.

2. The radiation detector of numbered paragraph 1, wherein: the SiPM has a relatively low response for a first range of light energies and a relatively high response for a second range of light energies; and the layer comprising metal is configured to provide, to the scintillator, additional radiation having energies to cause the scintillator to emit, to the SiPM, light in the first range of light energies.

3. The radiation detector of numbered paragraph 2, wherein the first range of light energies is lower than the second range of light energies.

4. The radiation detector of any preceding numbered paragraph, wherein the layer comprising metal is arranged to receive incident radiation and to provide additional radiation to the scintillator to increase the light emitted towards the SiPM.

5. The radiation detector of any preceding numbered paragraph, wherein the radiation detector is devoid of radiation absorbing material between the layer comprising metal and the scintillator.

6. The radiation detector of any preceding numbered paragraph, wherein the layer comprising metal comprises nickel.

7. The radiation detector of any preceding numbered paragraph, wherein the layer comprising metal comprises a metal having an atomic number of at least 15, at least 20, or at least 25.

8. The radiation detector of any preceding numbered paragraph, wherein the layer comprising metal comprises a mixture of metals.

9. The radiation detector of any preceding numbered paragraph, wherein the layer comprising metal comprises mylar.

10. The radiation detector of numbered paragraph 9, wherein the metal of the layer comprising metal is sputtered on the mylar.

11. The radiation detector of any preceding numbered paragraph, wherein the layer comprising metal is a thin film.

12. The radiation detector of any preceding numbered paragraph, wherein the layer comprising metal has a thickness of: greater than or equal to 1×10⁻⁶ m; greater than or equal to 2×10⁻⁶ m; or greater than or equal to 3×10⁻⁶ m.

13. The radiation detector of any preceding numbered paragraph, wherein the layer comprising metal has a thickness of: less than or equal to 10×10⁻⁶ m; less than or equal to 20×10⁻⁶ m; or less than or equal to 30×10⁻⁶ m.

14. The radiation detector of any preceding numbered paragraph, wherein the layer comprising metal is optically reflective.

15. The radiation detector of any preceding numbered paragraph, further comprising a substrate, wherein the SiPM is on the substrate.

16. The radiation detector of numbered paragraph 15, wherein the substrate is a printed circuit board (PCB).

17. The radiation detector of numbered paragraph 15 or numbered paragraph 16, wherein the substrate and the layer comprising metal define a chamber and the scintillator and/or the SiPM are within the chamber.

18. The radiation detector of any of numbered paragraphs 15 to 17, wherein the chamber comprises an opening for allowing air into and/or out of the chamber.

19. The radiation detector of numbered paragraph 18, wherein the opening is in the substrate.

20. The radiation detector of any preceding numbered paragraph, wherein the scintillator is an organic scintillator.

21. The radiation detector of any preceding numbered paragraph, wherein the scintillator is a plastic scintillator.

22. The radiation detector of any preceding numbered paragraph, wherein the scintillator comprises polyvinyltoluene (PVT).

23. The radiation detector of any preceding numbered paragraph, wherein the scintillator is between the layer comprising metal and the SiPM.

24. The radiation detector of any preceding numbered paragraph, wherein the scintillator is on the SiPM.

25. The radiation detector of any preceding numbered paragraph, wherein the scintillator is adhered to the SiPM.

26. The radiation detector of any preceding numbered paragraph, wherein the scintillator is adhered to the SiPM by a glue that is transparent to the light emitted by the scintillator.

27. The radiation detector of any preceding numbered paragraph, further comprising a substrate, wherein the SiPM is on the substrate, and wherein the layer comprising metal and the substrate surround the SiPM and the scintillator.

28. The radiation detector of any preceding numbered paragraph, wherein the layer comprising metal is configured to emit the additional radiation provided to the scintillator by the photoelectric effect and/or the Compton effect.

29. The radiation detector of any preceding numbered paragraph, wherein: the incident radiation is photons; and/or the additional radiation is electrons.

30. The radiation detector of any preceding numbered paragraph, wherein a distance between the layer comprising metal and the scintillator is: greater than or equal to 50×10⁻⁶ m; greater than or equal to 200×10⁻⁶ m; or greater than or equal to 500×10⁻⁶ m.

31. The radiation detector of any preceding numbered paragraph, wherein a distance between the layer comprising metal and the scintillator is: less than or equal to than 750×10⁻⁶ m; less than or equal to than 1000×10⁻⁶ m; or less than or equal to than 1500×10⁻⁶ m.

32. The radiation detector of any preceding numbered paragraph, further comprising a spacer arranged to hold the layer comprising metal in a position that that is spaced apart from the scintillator.

33. The radiation detector of numbered paragraph 32, wherein the spacer comprises an aperture.

34. The radiation detector of numbered paragraph 32 or numbered paragraph 33, wherein the aperture extends between a first surface of the spacer that is adjacent to the SiPM and a second surface of the spacer that is adjacent to the layer comprising metal.

35. The radiation detector of any of numbered paragraphs 32 to 34, wherein the aperture is substantially cylindrical.

36. The radiation detector of any of numbered paragraphs 32 to 35, wherein the scintillator and/or the SiPM are within the aperture of the spacer.

37. The radiation detector of any of numbered paragraphs 32 to 36, wherein an outer surface of the spacer is substantially cylindrical.

38. The radiation detector of any of numbered paragraphs 32 to 37, wherein the spacer is [at least partially] optically transparent.

39. The radiation detector of any of numbered paragraphs 32 to 38, wherein the spacer comprises acrylonitrile butadiene styrene (ABS).

40. The radiation detector of any preceding numbered paragraph, further comprising a light emitting device for testing the radiation detector.

41. The radiation detector of numbered paragraph 40, further comprising a spacer arranged to hold the layer comprising metal in a position that that is spaced apart from the scintillator, wherein the light emitting device is arranged to emit light through the spacer and towards the scintillator and/or the SiPM.

42. The radiation detector of numbered paragraph 40 or numbered paragraph 41, wherein the light emitting device comprises a light emitting diode (LED).

43. The radiation detector of any preceding numbered paragraph, further comprising a casing enclosing the SiPM, the scintillator and the layer comprising metal.

44. The radiation detector of numbered paragraph 43, wherein the casing is optically reflective.

45. The radiation detector of numbered paragraph 43 or 44, wherein the casing comprises aluminum.

46. The radiation detector of any of numbered paragraphs 43 to 45, wherein the casing is a film.

47. The radiation detector of any of numbered paragraphs 43 to 46, wherein the casing comprises aluminum tape.

48. The radiation detector of any of numbered paragraphs 43 to 47, further comprising a cable extending from outside the casing to inside the casing.

49. The radiation detector of numbered paragraph 48, wherein the cable is a flat cable.

50. The radiation detector of numbered paragraph 48 or numbered paragraph 49, wherein the cable has a meandering structure.

51. The radiation detector of any of numbered paragraphs 48 to 50, wherein the cable provides a connection to the SiPM.

52. The radiation detector of any of numbered paragraphs 48 to 51, wherein the cable is a power and/or data communication cable.

53. The radiation detector of any of numbered paragraphs 48 to 52, wherein the casing comprises a first portion and a second portion parallel to the first portion, and wherein the cable passes between the first portion of the casing and the second portion of the casing.

54. The radiation detector of numbered paragraph 53, wherein the first and second portions of the casing are adhered to each other.

55. The radiation detector of any of numbered paragraphs 48 to 54, wherein the cable extends along a first surface of the first portion of the casing.

56. The radiation detector of numbered paragraph 55, wherein the cable extends along a second surface of the first portion of the casing and a first surface of the second portion of the casing.

57. The radiation detector of numbered paragraph 56, wherein the cable extends along a second surface of the second portion of the casing.

58. The radiation detector of any of numbered paragraphs 55 to 57, wherein: the first surface of the first portion of the casing is an exterior surface and the second surface of the first portion of the casing is an interior surface; and/or the first surface of the second portion of the casing is an exterior surface and the second surface of the second portion of the casing is an interior surface.

59. The radiation detector of any of numbered paragraphs 48 to 58, wherein the cable comprises three flat portions that are mutually parallel.

60. The radiation detector of any of numbered paragraphs 48 to 59, wherein the cable is folded at least once and preferably at least twice.

61. The radiation detector of any of numbered paragraphs 48 to 60, wherein the casing is wrapped around the radiation detector, and wherein the first and second portions of the casing are overlapping.

62. A method of forming a radiation detector, the method comprising steps of: providing a spacer material; forming an aperture through the spacer material; attaching a layer comprising metal across the aperture of the spacer material, wherein the layer comprising metal is configured to receive incident radiation and to emit additional radiation in response to the received incident radiation; forming a spacer from the spacer material, the spacer comprising the aperture; and attaching the spacer to a substrate having a scintillator and a Silicon photomultiplier (SiPM) thereon, such that the scintillator and the SiPM are within the aperture and the layer comprising metal is spaced apart from the scintillator.

63. The method of numbered paragraph 62, comprising attaching the layer comprising metal using an adhesive.

64. The method of numbered paragraph 62 or numbered paragraph 63, wherein the aperture extends between first and second surfaces of the spacer material, the method further comprising applying first and second adhesives to the first and second surfaces of the spacer material.

65. The method of numbered paragraph 64, comprising attaching a transfer film to at least one of the first and/or second adhesives.

66. The method of numbered paragraph 65, comprising removing at least one transfer film before attaching the layer comprising metal across the aperture.

67. The method of any of numbered paragraphs 63 to 66, wherein the adhesive is double-sided tape.

68. The method of any of numbered paragraphs 62 to 67, wherein forming the aperture comprises cutting the spacer material, preferably by laser cutting.

69. The method of numbered paragraph 68, when dependent on numbered paragraph 63 and/or numbered paragraph 65, wherein forming the aperture comprises simultaneously cutting the spacer material, the adhesive and/or the transfer film, preferably by laser cutting.

70. The method of any of numbered paragraphs 62 to 69, wherein forming the spacer comprises removing a portion of the spacer material around the aperture and removing a portion of the layer comprising metal on the portion of the spacer material around the aperture.

71. The method of numbered paragraph 70, wherein removing the portion of the spacer material around the aperture occurs simultaneously with removing the portion of the layer comprising metal.

72. The method of any of numbered paragraph 71, wherein removing the portion of the spacer material around the aperture occurs simultaneously with removing a portion of transfer film attached to the spacer material.

73. The method of any of numbered paragraphs 70 to 72, wherein removing the portion of the spacer material around the aperture and the portion of the layer comprising metal comprises cutting the spacer material and the layer comprising metal, preferably by laser cutting.

74. The method of any of numbered paragraphs 70 to 73, wherein removing the portion of the spacer material around the aperture and removing the portion of the layer comprising metal occur simultaneously with removing a portion of transfer film attached to the spacer material.

75. The method of numbered paragraph 74, further comprising replacing the transfer film with a replacement transfer film.

76. The method of numbered paragraph 75, wherein forming the spacer comprises cutting the replacement transfer film to separate the layer comprising metal, the spacer and the replacement transfer film from the portion of the spacer material, preferably by laser cutting.

77. The method of any of numbered paragraphs 74 to 76, comprising: partially cutting the layer comprising metal, the spacer and the transfer film; replacing the transfer film with a replacement transfer film; and completing cutting the layer comprising metal, the spacer and the transfer film.

78. The method of any of numbered paragraphs 62 to 77, comprising removing the spacer from the spacer material by pressing the spacer from the spacer material.

79. The method of any of numbered paragraphs 62 to 78, comprising attaching the spacer material to the substrate using an adhesive.

80. The method of any of numbered paragraphs 62 to 79, wherein the method is for making the radiation detector of any of numbered paragraphs 1 to 61.

81. A radiation detector comprising: a silicon photomultiplier (SiPM); a scintillator arranged to emit light towards the SiPM; a casing enclosing the SiPM and the scintillator, wherein the casing comprises a first portion and a second portion parallel to the first portion of the casing; and a flat cable extending from outside the casing to inside the casing, wherein the cable is folded at least once and passes between the first portion of the casing and the second portion of the casing.

82. The radiation detector of numbered paragraph 81, wherein the casing is optically reflective.

83. The radiation detector of numbered paragraph 81 or 82, wherein the casing comprises aluminum.

84. The radiation detector of any of numbered paragraphs 81 to 83, wherein the casing is a film.

85. The radiation detector of any of numbered paragraphs 81 to 84, wherein the casing comprises aluminum tape.

86. The radiation detector of any of numbered paragraphs 81 to 85, wherein the cable has a meandering structure.

87. The radiation detector of any of numbered paragraphs 81 to 86, wherein the cable provides a connection to the SiPM.

88. The radiation detector of any of numbered paragraphs 81 to 87, wherein the cable is a power and/or data communication cable.

89. The radiation detector of numbered paragraph 88, wherein the first and second portions of the casing are adhered to each other.

90. The radiation detector of any of numbered paragraphs 81 to 89, wherein the cable extends along a first surface of the first portion of the casing.

91. The radiation detector of numbered paragraph 90, wherein the cable extends along a second surface of the first portion of the casing and a first surface of the second portion of the casing.

92. The radiation detector of numbered paragraph 91, wherein the cable extends along a second surface of the second portion of the casing.

93. The radiation detector of any of numbered paragraphs 90 to 92, wherein: the first surface of the first portion of the casing is an exterior surface and the second surface of the first portion of the casing is an interior surface; and/or the first surface of the second portion of the casing is an exterior surface and the second surface of the second portion of the casing is an interior surface.

94. The radiation detector of numbered paragraph any of numbered paragraphs 81 to 93, wherein the cable comprises three flat portions that are mutually parallel.

95. The radiation detector of any of numbered paragraphs 81 to 94, wherein the cable is folded at least twice.

96. The radiation detector of any of numbered paragraphs 81 to 95, wherein the casing is wrapped around the radiation detector, and wherein the first and second portions of the casing are overlapping.

It will be understood that many variations may be made to the above apparatus, systems and methods whilst retaining the advantages noted previously. For example, where specific components have been described, alternative components can be provided that provide the same or similar functionality.

Each feature disclosed in this specification, unless stated otherwise, may be replaced by alternative features serving the same, equivalent or similar purpose. Thus, unless stated otherwise, each feature disclosed is one example only of a generic series of equivalent or similar features.

As used herein, including in the claims, unless the context indicates otherwise, singular forms of the terms herein are to be construed as including the plural form and, where the context allows, vice versa. For instance, unless the context indicates otherwise, a singular reference herein including in the claims, such as “a” or “an” (such as a detector or a photomultiplier) means “one or more” (for instance, one or more detectors, or one or more photomultipliers). Throughout the description and claims of this disclosure, the words “comprise”, “including”, “having” and “contain” and variations of the words, for example “comprising” and “comprises” or similar, mean that the described feature includes the additional features that follow, and are not intended to (and do not) exclude the presence of other components.

The use of any and all examples, or exemplary language (“for instance”, “such as”, “for example” and like language) provided herein, is intended merely to better illustrate the disclosure and does not indicate a limitation on the scope of the disclosure unless otherwise claimed. No language in the specification should be construed as indicating any non-claimed element as essential to the practice of the disclosure.

Any steps described in this specification may be performed in any order or simultaneously unless stated or the context requires otherwise. Moreover, where a step is described as being performed after a step, this does not preclude intervening steps being performed.

All of the aspects and/or features disclosed in this specification may be combined in any combination, except combinations where at least some of such features and/or steps are mutually exclusive. In particular, the preferred features of the disclosure are applicable to all aspects and embodiments of the disclosure and may be used in any combination. Likewise, features described in non-essential combinations may be used separately (not in combination).

1-96. (canceled)

97. A radiation detector comprising:
a silicon photomultiplier (SiPM);
a scintillator arranged to emit light towards the SiPM; and
a layer comprising metal that is spaced apart from the scintillator, wherein the layer comprising metal is configured to receive incident radiation and to provide additional radiation to the scintillator in response to the received incident radiation.

98. The radiation detector of claim 97, wherein:
the SiPM has a relatively low response for a first range of light energies and a relatively high response for a second range of light energies; and
the layer comprising metal is configured to provide, to the scintillator, additional radiation having energies to cause the scintillator to emit, to the SiPM, light in the first range of light energies.

99. The radiation detector of claim 98, wherein the first range of light energies is lower than the second range of light energies.

100. The radiation detector of claim 97, wherein the layer comprising metal is arranged to receive incident radiation and to provide additional radiation to the scintillator to increase the light emitted towards the SiPM.

101. The radiation detector of claim 97, wherein the layer comprising metal comprises nickel.

102. The radiation detector of claim 97, wherein the layer comprising metal comprises a metal having an atomic number of at least 15.

103. The radiation detector of claim 97, wherein the layer comprising metal comprises a mixture of metals.

104. The radiation detector of claim 97, wherein the layer comprising metal has a thickness of greater than or equal to 1×10⁻⁶ m.

105. The radiation detector of claim 97, further comprising a substrate, wherein the SiPM is on the substrate, and wherein the substrate and the layer comprising metal define a chamber, and at least one of the scintillator and the SiPM are within the chamber.

106. The radiation detector of claim 97, wherein the scintillator is an organic scintillator.

107. The radiation detector of claim 97, wherein the scintillator is a plastic scintillator.

108. The radiation detector of claim 97, wherein the scintillator is between the layer comprising metal and the SiPM.

109. The radiation detector of claim 97, wherein the scintillator is on the SiPM.

110. The radiation detector of claim 97, wherein a distance between the layer comprising metal and the scintillator is greater than or equal to 50×10⁻⁶ m.

111. The radiation detector of claim 97, wherein the scintillator comprises polyvinyltoluene (PVT).

112. The radiation detector of claim 97, further comprising a spacer arranged to hold the layer comprising metal in a position that that is spaced apart from the scintillator, wherein the spacer defines an aperture that extends between a first surface of the spacer that is adjacent to the SiPM and a second surface of the spacer that is adjacent to the layer comprising metal.

113. The radiation detector of any of claim 112, wherein the aperture is substantially cylindrical.

114. The radiation detector of claim 112, wherein at least one of the scintillator and the SiPM are within the aperture defined in the spacer.

115. A method of forming a radiation detector, the method comprising steps of:
providing a spacer material;
forming an aperture through the spacer material;
attaching a layer comprising metal across the aperture of the spacer material, wherein the layer comprising metal is configured to receive incident radiation and to emit additional radiation in response to the received incident radiation;
forming a spacer from the spacer material, the spacer defining the aperture; and
attaching the spacer to a substrate having a scintillator and a silicon photomultiplier (SiPM) thereon, such that the scintillator and the SiPM are within the aperture and the layer comprising metal is spaced apart from the scintillator.

116. The method of claim 115, comprising attaching the layer comprising metal using an adhesive.

117. The method of claim 115, wherein the aperture extends between first and second surfaces of the spacer material, the method further comprising applying first and second adhesives to the first and second surfaces of the spacer material.

118. A radiation detector comprising:
a SiPM;
a scintillator arranged to emit light towards the SiPM;
a casing enclosing the SiPM and the scintillator, wherein the casing comprises a first portion and a second portion parallel to the first portion; and
a flat cable extending from outside the casing to inside the casing, wherein the flat cable is folded at least once and passes between the first portion of the casing and the second portion of the casing.

119. The radiation detector of claim 118, wherein the casing is optically reflective and is situated to reflect at least portions of the emitted light toward the SiPM.

120. The radiation detector of claim 118, wherein the flat cable has a meandering structure.
